(19) United States
(12) Patent Application Publication
(10) Pub. No.: US 2006/0011971 A1
(43) Pub. Date: Jan. 19, 2006

(54) Nonvolatile semiconductor memory device and method of manufacturing the same

(75) Inventor: Hideki Hara, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronic Corporation, Kawasaki (JP)

(21) Appl. No.: 11/176,157

(22) Filed: Jul. 8, 2005

(30) Foreign Application Priority Data
Jul. 13, 2004 (JP) 206194/2004

(51) Int. Cl. H01L 29/788

(52) U.S. Cl. 257/316; 257/315; 257/320

(57) ABSTRACT

A nonvolatile semiconductor memory device has a substrate, a floating gate, a buried gate, a control gate, and source/drain regions. The substrate has a trench formed in a first direction. The floating gate is formed on a surface of the substrate outside the trench through a first gate insulating film. The buried gate is formed on a surface of the trench through a second gate insulating film. The control gate is formed to cover the floating gate through a third gate insulating film. The source/drain regions are formed in the substrate below the floating gate.

### BACKGROUND OF THE INVENTION

1. Field of the Invention

The present invention relates to a nonvolatile semiconductor memory device and a method of manufacturing the same.

2. Description of the Related Art

FIG. 1 is a plan view schematically showing a structure of a nonvolatile semiconductor memory device according to a conventional technique. FIGS. 2A to 2C are cross-sectional views of the nonvolatile semiconductor memory device along lines a-a′, b-b′, and c-c′ in FIG. 1, respectively.

As shown in FIGS. 1 and 2A to 2C, the nonvolatile semiconductor memory device 100 includes a substrate 110 having a trench 120, a floating gate 140 formed on the substrate 110 through a tunnel oxide film 111, a control gate 150 formed to cover the floating gate 140 through an oxide-nitride-oxide (ONO) film 131, a source region 161, and a drain region 162. An oxide film 123 is buried into the trench 120 which is used for the device isolation. Also, an impurity layer 130 is formed at the bottom of the trench 120. As shown in FIG. 2A, connected to the control gate 150 is a word line 133. As shown in FIG. 2B, connected to the drain region 162 is a contact plug 191 which is formed to penetrate an interlayer insulating film 171, and a bit line 192 is connected to the contact plug 191. As shown in FIG. 2C, the source region 161 is formed along the surface of the substrate 110 in accordance with a shape of the trench 120. The source region 161 forms a source line.

In order to scale down memory cells, it is necessary to make the trench 120 deeper and thereby improve the device isolation characteristic in the nonvolatile semiconductor memory device 100 configured as stated above. However, as the trench 120 becomes deeper, it becomes more difficult to introduce impurities into a side wall of the trench 120 and thereby to form the source region 161 (see FIG. 2C). Also, a resistance (“source resistance”) of the source line formed in accordance with the shape of the trench 120 becomes higher. Furthermore, as the trench 120 becomes deeper, it becomes more difficult to bury an oxide film into the trench 120, which causes formation of cavities and hence malfunctions of the memory device. Recently, capacity of the nonvolatile semiconductor memory device has increased steadily, and it is desired to further scale down the memory cells and to further increase the integration density.

Japanese Laid Open Patent Application (JP-P2001-118939) discloses another nonvolatile semiconductor memory device. The nonvolatile semiconductor memory device includes a first conductivity type semiconductor substrate having a trench formed in one direction, a first gate insulating film formed on an entire surface inside the trench, a floating gate, second conductivity type impurity diffused layers, and a control gate. The floating gate is buried in the trench, and an upper portion of the floating gate protrudes from a surface of the semiconductor substrate. The second conductivity type impurity diffused layers are formed in both sides of the trench so as to face the floating gate through the first gate insulating film. The control gate extends onto the floating gate from above the semiconductor substrate.

### SUMMARY OF THE INVENTION

It has now been discovered that when the trench is made deeper in order to ensure the device isolation and thereby scale down the memory cells as in the conventional technique, it becomes more difficult to bury an oxide film into the trench. This causes the formation of cavities in the nonvolatile semiconductor memory device and hence the malfunctions thereof.

According to the present invention, a nonvolatile semiconductor memory device has a substrate, a floating gate, a buried gate, a control gate, and source/drain regions. The substrate has a trench formed in a first direction. The floating gate is formed on a surface of the substrate outside the trench through a first gate insulating film. The buried gate is formed on a surface of the trench through a second gate insulating film. The control gate is formed to cover the floating gate through a third gate insulating film. The source/drain regions are formed in the substrate below the floating gate.

According to the nonvolatile semiconductor memory device thus constructed, a negative electric potential can be applied to the above-mentioned buried gate when the substrate is a P-type semiconductor substrate. As a result, the device isolation is actively controlled and is improved without increasing the depth of the trench. Since the device isolation characteristic is improved, it is possible to prevent a punch-through between the drain regions and to reduce a distance between the drain regions. Thus, sizes of memory cells can be reduced, and integration density can be increased.

Moreover, it is not necessary according to the present invention to make the trench deeper for improving the device isolation characteristic. The device isolation is ensured without increasing the depth of the trench. Thus, burying a film into the trench is easier as compared with the conventional technique. In other words, a “burying ability” is improved. As a result, occurrence of the failures such as cavities is suppressed in a burying process, and thus malfunctions of the memory device are suppressed. Since the malfunctions are suppressed, yield of the memory device is improved. From the aspect of the “burying ability”, it is preferable that the buried gate is made of polysilicon.

According to the present invention, as described above, the memory cells are scaled down and the integration density is increased. Furthermore, the malfunctions of the nonvolatile semiconductor memory device are suppressed and hence the yield is improved.

### BRIEF DESCRIPTION OF THE DRAWINGS

The above and other objects, advantages and features of the present invention will be more apparent from the following description taken in conjunction with the accompanying drawings, in which:

FIG. 1 is a plan view schematically showing a structure of a nonvolatile semiconductor memory device according to a conventional technique;

FIG. 2A is a cross-sectional view along a line a-a′ in FIG. 1 showing the structure of the conventional nonvolatile semiconductor memory device;

FIG. 2B is a cross-sectional view along a line b-b′ in FIG. 1 showing the structure of the conventional nonvolatile semiconductor memory device;

FIG. 2C is a cross-sectional view along a line c-c′ in FIG. 1 showing the structure of the conventional nonvolatile semiconductor memory device;

FIG. 3 is a plan view schematically showing a structure of a nonvolatile semiconductor memory device according to an embodiment of the present invention;

FIG. 4A is a cross-sectional view along a line A-A′ in FIG. 3 showing the structure of the nonvolatile semiconductor memory device according to the present embodiment;

FIG. 4B is a cross-sectional view along a line B-B′ in FIG. 3 showing the structure of the nonvolatile semiconductor memory device according to the present embodiment;

FIG. 4C is a cross-sectional view along a line C-C′ in FIG. 3 showing the structure of the nonvolatile semiconductor memory device according to the present embodiment;

FIG. 4D is a cross-sectional view along a line D-D′ in FIG. 3 showing the structure of the nonvolatile semiconductor memory device according to the present embodiment;

FIG. 4E is a cross-sectional view along a line E-E′ in FIG. 3 showing the structure of the nonvolatile semiconductor memory device according to the present embodiment;

FIG. 4F is a cross-sectional view along a line F-F′ in FIG. 3 showing the structure of the nonvolatile semiconductor memory device according to the present embodiment;

FIG. 5 is a cross-sectional view along the line A-A′ in FIG. 3 showing a process of manufacturing the nonvolatile semiconductor memory device according to the present embodiment;

FIG. 6 is a cross-sectional view along the line A-A′ in FIG. 3 showing a process of manufacturing the nonvolatile semiconductor memory device according to the present embodiment;

FIG. 7 is a cross-sectional view along the line A-A′ in FIG. 3 showing a process of manufacturing the nonvolatile semiconductor memory device according to the present embodiment;

FIG. 8 is a cross-sectional view along the line A-A′ in FIG. 3 showing a process of manufacturing the nonvolatile semiconductor memory device according to the present embodiment;

FIG. 9 is a cross-sectional view along the line A-A′ in FIG. 3 showing a process of manufacturing the nonvolatile semiconductor memory device according to the present embodiment;

FIG. 10 is a cross-sectional view along the line A-A′ in FIG. 3 showing a process of manufacturing the nonvolatile semiconductor memory device according to the present embodiment;

FIG. 11 is a cross-sectional view along the line A-A′ in FIG. 3 showing a process of manufacturing the nonvolatile semiconductor memory device according to the present embodiment;

FIG. 12 is a cross-sectional view along the line D-D′ in FIG. 3 showing a process of manufacturing the nonvolatile semiconductor memory device according to the present embodiment;

FIG. 13 is a cross-sectional view along the line D-D′ in FIG. 3 showing a process of manufacturing the nonvolatile semiconductor memory device according to the present embodiment;

FIG. 14 is a cross-sectional view along the line D-D′ in FIG. 3 showing a process of manufacturing the nonvolatile semiconductor memory device according to the present embodiment;

FIG. 15 is a cross-sectional view along the line D-D′ in FIG. 3 showing a process of manufacturing the nonvolatile semiconductor memory device according to the present embodiment;

FIG. 16 is a cross-sectional view along the line D-D′ in FIG. 3 showing a process of manufacturing the nonvolatile semiconductor memory device according to the present embodiment;

FIG. 17 is a cross-sectional view along the line D-D′ in FIG. 3 showing a process of manufacturing the nonvolatile semiconductor memory device according to the present embodiment;

FIG. 18 is a cross-sectional view along the line F-F′ in FIG. 3 showing a process of manufacturing the nonvolatile semiconductor memory device according to the present embodiment; and

FIG. 19 is a cross-sectional view along the line D-D′ in FIG. 3 showing a process of manufacturing the nonvolatile semiconductor memory device according to the present embodiment.

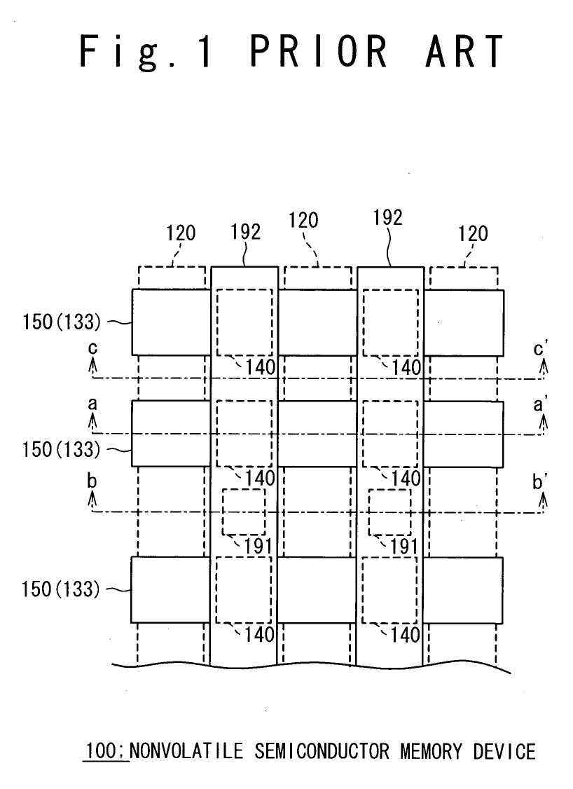

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

(Structure)

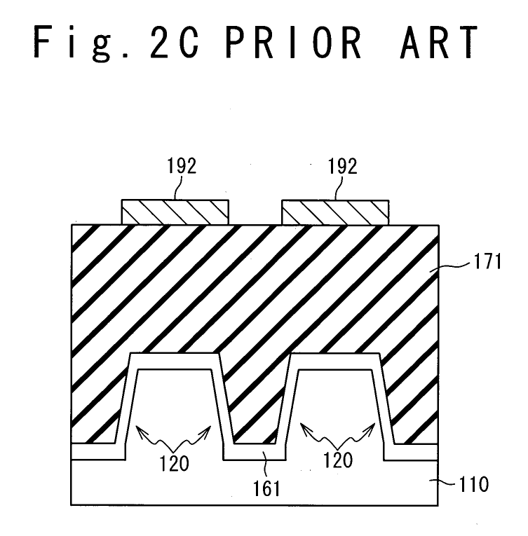

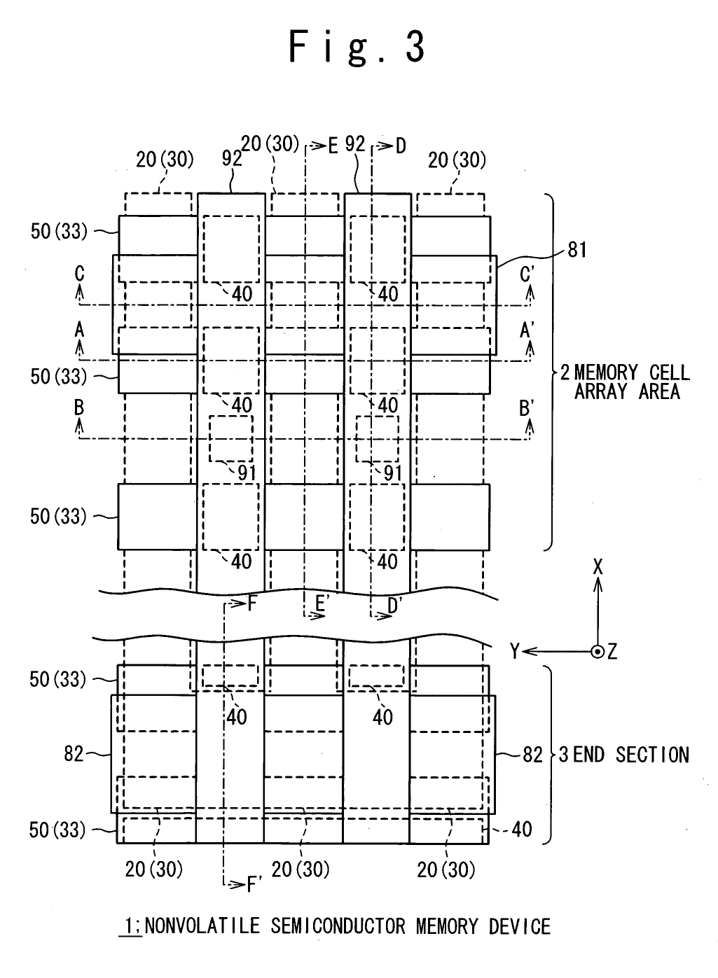

FIG. 3 is a plan view schematically showing a structure of a nonvolatile semiconductor memory device according to an embodiment of the present invention. FIGS. 4A to 4F are cross-sectional views along broken lines A-A′, B-B′, C-C′, D-D′, E-E′, and F-F′ in FIG. 3, respectively.

In the nonvolatile semiconductor memory device 1, as shown in FIG. 3, a bit line (a drain wirings 92) is formed in an X-direction (a first direction), and a word line (a control gate 50; a metal film 33) is formed in a Y-direction (a second direction). A Z-direction (a third direction) is defined as a normal direction of a substrate. These X-direction, Y-direction, and Z-direction are orthogonal to one another. In FIG. 3, the bit lines intersect with the word lines at a plurality of intersections, and a plurality of memory cells are provided at the plurality of intersections, respectively. A memory cell array region 2 shown in FIG. 3 includes the plurality of memory cells.

As will be described later in detail with reference to FIGS. 4A to 4F, the nonvolatile semiconductor memory device 1 according to the present embodiment has a substrate 10, a floating gate 40, a control gate 50, a source region 61, a drain region 62, and a buried gate 30.

The substrate 10 is, for example, a P-type silicon substrate. On the substrate 10, a plurality of trenches 20 are formed which are used for the device isolation. As shown in FIG. 3, the plurality of trenches 20 are formed substantially parallel to one another in the X-direction. The above-mentioned Z-direction can be also defined as a depth direction of the trench 20.

As shown in FIG. 4A, the floating gate 40 is formed on a surface of the substrate 10 outside the trench 20 through a first gate insulating film 11. The floating gate 40 is made of, for example, polysilicon doped with N type impurities. The first gate insulating film 11 is, for example, an SiO₂ film having a thickness of 9 nanometers (nm) and functions as “a tunnel oxide film”.

The buried gate 30 is formed on a surface of the trench 20 through a second gate insulating film 21. The buried gate 30 is formed to extend in the X-direction. The second gate insulating film 21 is, for example, an SiO₂ film with a thickness of 10 nm. The buried gate 30 is made of, for example, polysilicon doped with N type impurities. Since polysilicon instead of an oxide film is buried into the trench 20 having a relatively high aspect ratio, the “burying ability” of burying the buried gate 30 into the trench 20 is favorably improved. Moreover, as shown in FIG. 4A, the buried gate 30 is buried into the trench 20. Namely, the buried gate 30 is formed below the first gate insulating film 11. In this case, sufficient breakdown voltage is ensured between the buried gate 30 and the above-mentioned floating gate 40, which is preferable. It is more preferable that a distance d between an upper surface of the buried gate 30 and the first gate insulating film 11 in the Z-direction is equal to or larger than 10 nm.

Also, an oxide film 23 is formed on the buried gate 30. A third gate insulating film 31 is formed to cover the oxide film 23 and the above-mentioned floating gate 40. The third gate insulating film 31 is, for example, an oxide-nitride-oxide (ONO) film. Further, a control gate 50 is formed on the third gate insulating film 31 to cover the floating gate 40. The control gate 50 is made of, for example, polysilicon doped with the N type impurities. As shown in FIGS. 3 and 4A, the control gate 50 is formed to extend in the Y-direction. As shown in FIG. 4A, the control gate 50 is formed to cover an upper surface and a part of side surfaces of the floating gate 40, which is preferable from the view point of capacity coupling. A metal film 33 made of, for example, tungsten silicide (WSi) is formed on the control gate 50. An interlayer insulating film 71 is formed on the metal film 33.

As shown in FIG. 4B, the drain region 62 is formed within the substrate 10 by introducing, for example, N type impurities. The drain region 62 is formed in an active region isolated by the trenches 20, i.e., within the substrate 10 below the floating gate 40. Connected with the drain region 62 is a contact plug 91 which is formed to penetrate the interlayer insulating film 71. The contact plug 91 is made of tungsten (W). Also, a drain wiring (an upper wiring) 92 made of aluminum (Al) is formed on the interlayer insulating film 71, and is connected with the contact plug 91. As shown in FIG. 3, the drain wiring 92 is formed to extend in the X-direction and functions as “a bit line”.

As shown in FIG. 4C, the source region 61 is formed within the substrate 10 by introducing, for example, N type impurities. The source region 61 is formed in an active region isolated by the trenches 20, i.e., within the substrate 10 below the floating gate 40. Connected with the source region 61 is a source wiring (a first intermediate wiring) 81 formed to extend in the Y-direction. The source wiring 81 is made of tungsten (W). As shown in FIG. 4C, the source wiring 81 is formed within the interlayer insulating film 71, i.e., formed in “an intermediate layer” between the drain wiring 92 and the substrate 10.

As shown in FIG. 4D, the floating gate 40 is formed on the substrate 10 through the first gate insulating film 11. The control gate 50 is formed on the floating gate 40 through the third gate insulating film 31. One floating gate 40 and one control gate 50 are isolated from another floating gate 40 and another control gate 50 in the X direction, respectively. Gate sidewalls 70 are formed on side surfaces of the floating gate 40 and the control gate 50. The respective memory cells are thus configured. Also, the source region 61 and the drain region 62 are formed within the substrate 10 below the floating gate 40. The source region 61 and the drain region 62 are formed in the substrate 10 on both sides of the floating gate 40 so as to face one another. The drain wiring 92 formed on the interlayer insulating film 71 in the X-direction is connected to the drain region 62 through the contact plugs 91. The source wiring 81 connected to the source region 61 is formed in the Y-direction in the intermediate layer between the drain wiring 92 and the substrate 10.

As shown in FIG. 4E, the second gate insulating film 21 is formed on the substrate 10 within the trench 20, and the buried gate 30 is formed on the second gate insulating film 21. The buried gate 30 is formed in the X-direction.

As described above, the trenches 20 are formed substantially parallel to one another in the X-direction on the substrate 10. The buried gates 30 are buried into the respective trenches 20. Therefore, these buried gates 30 are formed substantially parallel to one another in the X-direction similarly to the trenches 20. However, it should be noted that the buried gates 30 are formed to be contact with one another along the Y-direction at an end section 3 of the memory cell array, as shown in FIG. 3. At the end section 3 of the memory cell array, a buried gate wiring 82 is formed to be contact with the buried gates 30. The buried gate wiring 82 is also formed to extend in the Y-direction. A predetermined electric potential is applied to the buried gates 30 through this buried gate wiring 82.

As shown in FIG. 4F, the buried gate wiring 82 extending in the Y-direction is formed to connect to the buried gate 30. Similarly to the above-mentioned source wiring 81 (first intermediate wiring), the buried gate wiring 82 (second intermediate wiring) is formed in the “intermediate layer” between the drain wiring 92 and the substrate 10. The buried gate wiring 82 is made of tungsten (W) similarly to the source wiring 81. In this case, the buried gate wiring 82 can be easily formed in the same process as that of forming the source wiring 81, which is preferable.

In the nonvolatile semiconductor memory device 1 configured as stated above, the buried gate 30 plays the following roles. In a case when the substrate 10 is a P type semiconductor substrate, a negative electric potential is applied to the buried gate 30 through the buried gate wiring 82 at the time of data writing and reading. The negative electric potential is, for example, −2 to −3 V. The negative electric potential thus applied can prevent the punch-through between the drain regions 62. Namely, by applying the negative electric potential to the buried gate 30 buried into the trench 20, the device isolation is actively controlled and is improved without increasing the depth of the trench 20. Since the device isolation characteristic is improved, it is possible to reduce a distance between the drain regions 62. Thus, sizes of the memory cells can be reduced, and the integration density can be increased.

As described above, it is not necessary according to the present embodiment to make the trench 20 deeper for improving the device isolation characteristic. The device isolation is ensured without increasing the depth of the trench 20. It is therefore possible to bury a film into the trench 20 easily. In other words, the “burying ability” with respect to the trench 20 having a relatively high aspect ratio can be improved. As a result, occurrence of the failures such as cavities is suppressed in a burying process, and thus malfunctions of the nonvolatile semiconductor memory device 1 are suppressed. Since the malfunctions are suppressed, yield of the nonvolatile semiconductor memory device 1 is improved. From the view point of the “burying ability”, it is preferable that the buried gate 30 is made of polysilicon.

Also, with reference to FIG. 4A, the buried gate 30 is formed below the first gate insulating film 11, which is preferable from a view point of ensuring the sufficient breakdown voltage between the buried gate 30 and the floating gate 40. It is particularly preferable that the distance d between the upper surface of the buried gate 30 and the first gate insulating film 11 in the Z-direction is equal to or larger than 10 nm, since sufficient breakdown voltage can be achieved. Moreover, when the buried gate 30 is formed below the first gate insulating film 11, the control gate 50 can be formed to sufficiently cover not only the upper surface of the floating gate 40 but also the side surfaces thereof, as shown in FIG. 4A. In this case, the capacity coupling between the control gate 50 and the floating gate 40 is improved, which is further preferable.

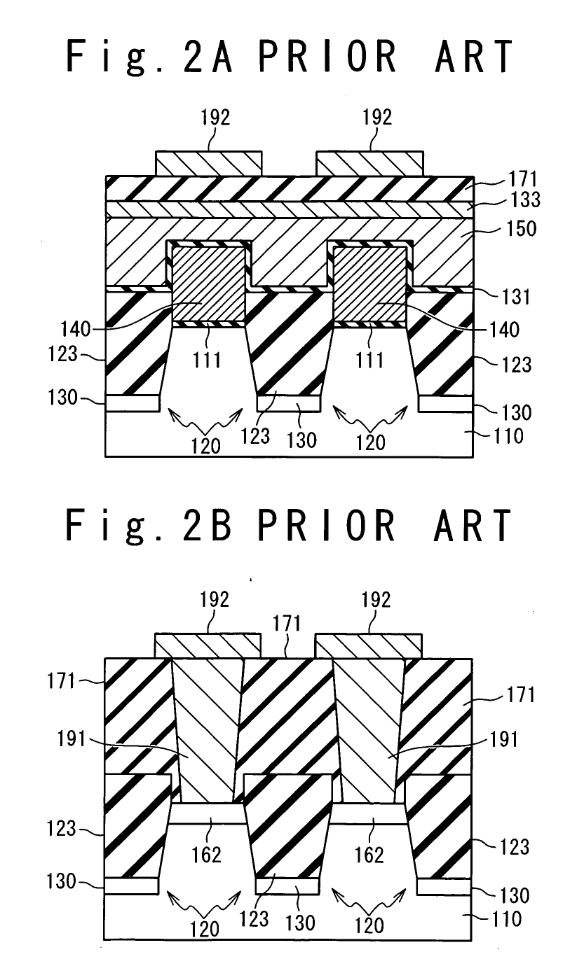

Furthermore, according to the present embodiment, the buried gate 30 is formed within the trench 20. As a result, the source wiring 81 is formed in the “intermediate layer” between the drain wiring 92 and the substrate 10, as shown in FIGS. 4C and 4D. Due to this configuration, additional advantages can be obtained as follows. That is to say, a resistance (source resistance) of the source wiring 81 can be reduced, since it is unnecessary to form the source wiring 81 in accordance with the shape of the trench 20 (see FIG. 2C, the conventional technique). In addition, it is possible to form the source wiring 81 easily irrespective of the depth of the trench 20. As described above, according to the nonvolatile semiconductor memory device 1 of the present embodiment, the source resistance is reduced, so that a memory cell operating current is ensured and an operation margin is widened. Similarly to this source wiring (first intermediate wiring) 81, the buried gate wiring (second intermediate wiring) 82 for applying a predetermined voltage to each buried gate 30 is formed in the “intermediate layer”.

(Manufacturing Method)

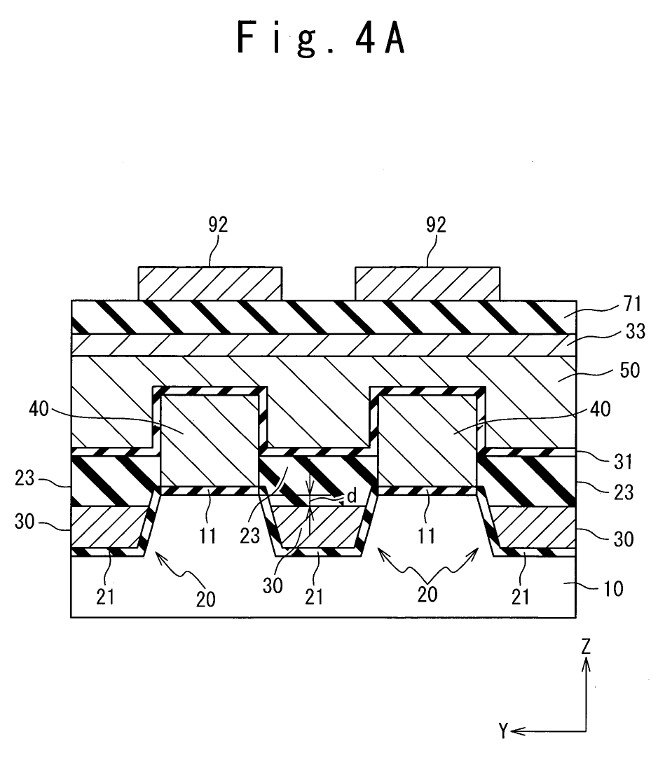

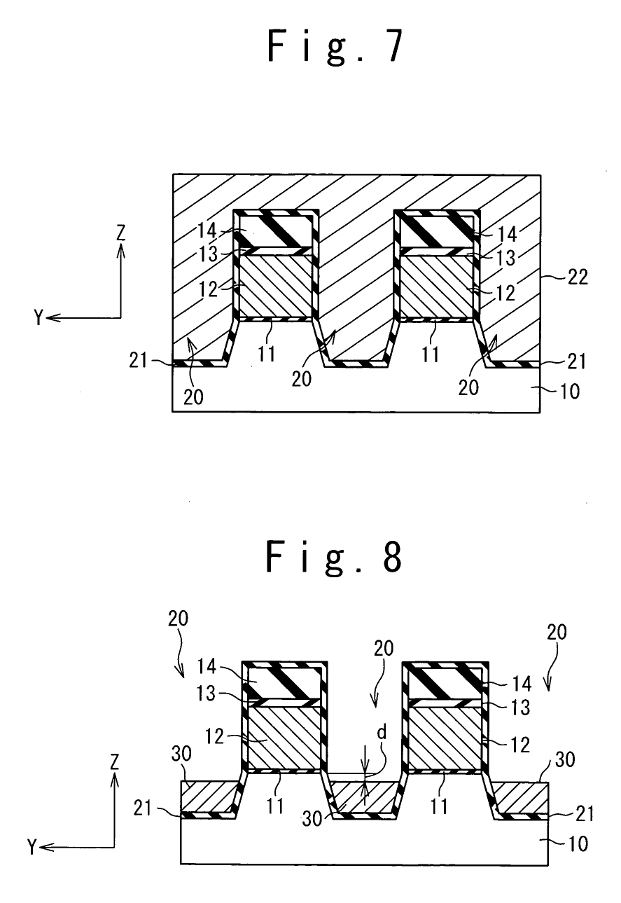

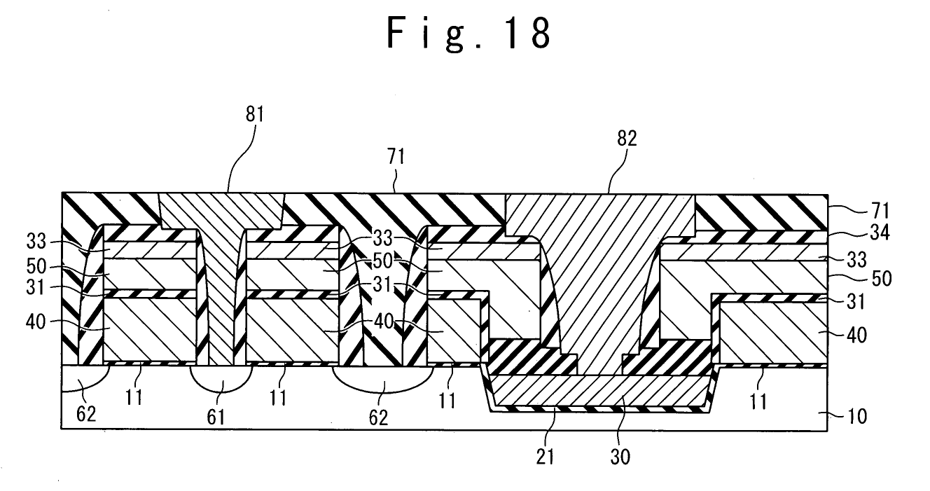

Next, a method of manufacturing the nonvolatile semiconductor memory device 1 configured as stated above will be described. FIGS. 5 to 11 are cross-sectional views along the line A-A′ showing processes of manufacturing the nonvolatile semiconductor memory device 1 according to the present embodiment. FIGS. 12 to 17 and 19 are cross-sectional views along the line D-D′ showing processes of manufacturing the nonvolatile semiconductor memory device 1 according to the present embodiment. FIG. 18 is a cross-sectional view along the line F-F′ showing a process of manufacturing the nonvolatile semiconductor memory device according to the present embodiment.

First, as shown in FIG. 5, a first gate insulating film 11 is formed on the substrate 10. For example, the substrate 10 is a P type silicon substrate, and the first gate insulating film 11 is an SiO₂ film with a thickness of about 9 nm. Next, a first polysilicon film 12 having a thickness of about 150 nm is formed on the first gate insulating film 11. The first polysilicon film 12 is doped with the N type impurities. Next, an oxide film 13 having a thickness of about 10 nm is formed on the first polysilicon film 12, and a nitride film 14 with a thickness of about 100 nm is formed on the oxide film 13.

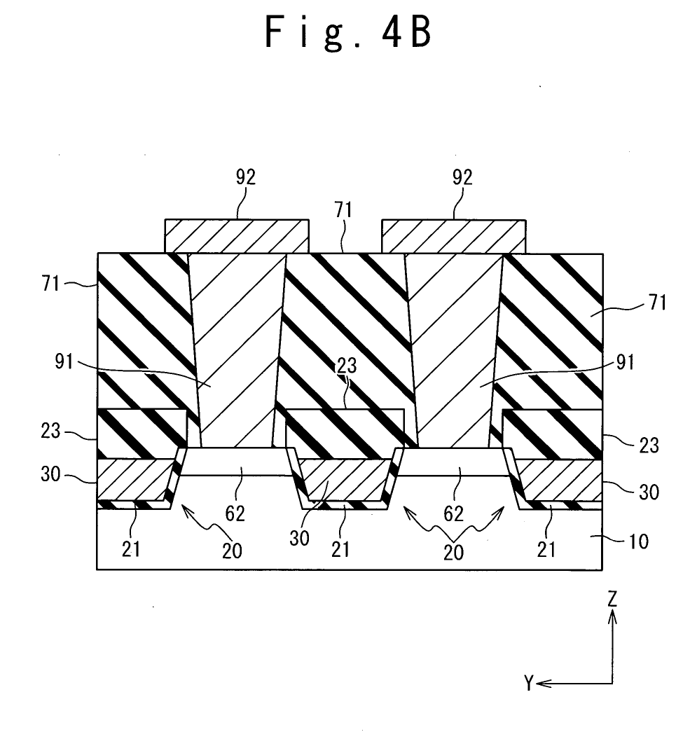

Next, the nitride film 14, the oxide film 13, the first polysilicon film 12, the first gate insulating film 11, and the substrate 10 are etched in this order by using a mask having a predetermined pattern along the X-direction. Accordingly, as shown in FIG. 6, trench regions 20 are formed in the X-direction. The trench region 20 penetrates the nitride film 14, the oxide film 13, the first polysilicon film 12, and the first gate insulating film 11 to reach below a surface of the substrate 10.

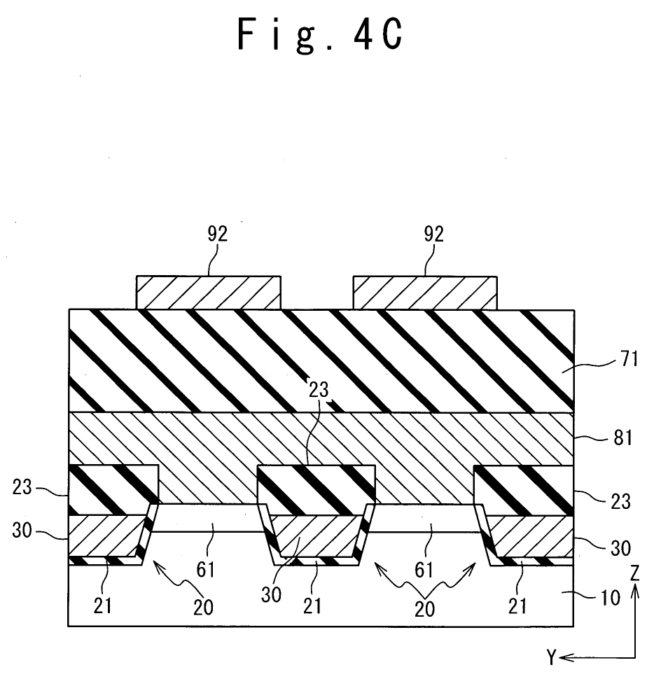

Next, as shown in FIG. 7, a second gate insulating film 21 is formed on an entire surface, and a second polysilicon film 22 is formed on the second gate insulating film 21. The second gate insulating film 21 is an SiO₂ film having a thickness of about 10 nm. The second polysilicon film 22 is doped with N type impurities. In this way, the second polysilicon film 22 is buried into the trench regions 20 through the second gate insulating film 21.

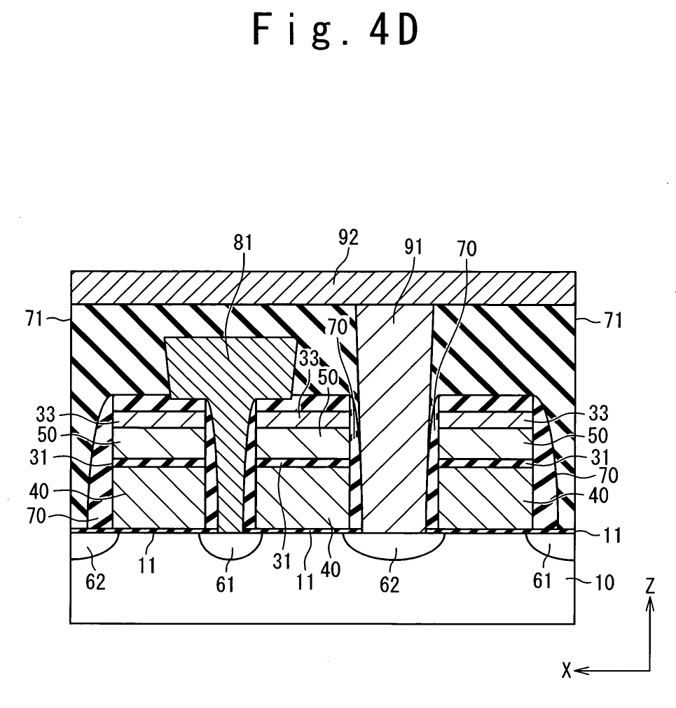

Next, the second polysilicon film 22 is etched such that a part of the second polysilicon film 22 is left in the trench regions 20. As a result, as shown in FIG. 8, the above-mentioned buried gate 30 made of the second polysilicon film 22 is formed within each trench 20. Here, the second polysilicon film 22 is etched such that an upper surface of the formed buried gate 30 is located below the first gate insulating film 11. More specifically, the etching is performed until the distance d between the upper surface of the buried gate 30 and the first gate insulating film 11 in the Z-direction becomes at least 10 nm.

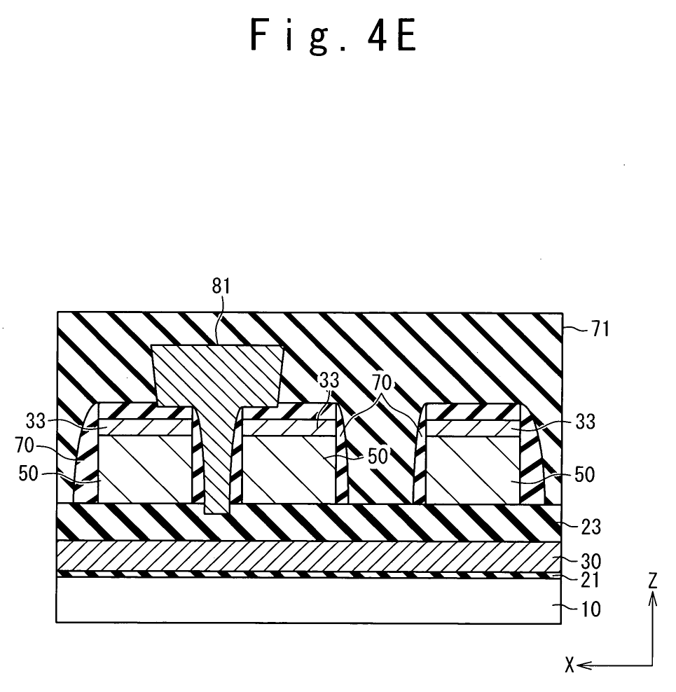

Next, an oxide film (SiO₂ film) 23 is formed on an entire surface through a plasma chemical vapor deposition (plasma CVD) method or the like. Then, a planarization is carried out through a chemical mechanical polishing (CMP) or the like. As a result, as shown in FIG. 9, the oxide film 23 is buried into the trench region 20.

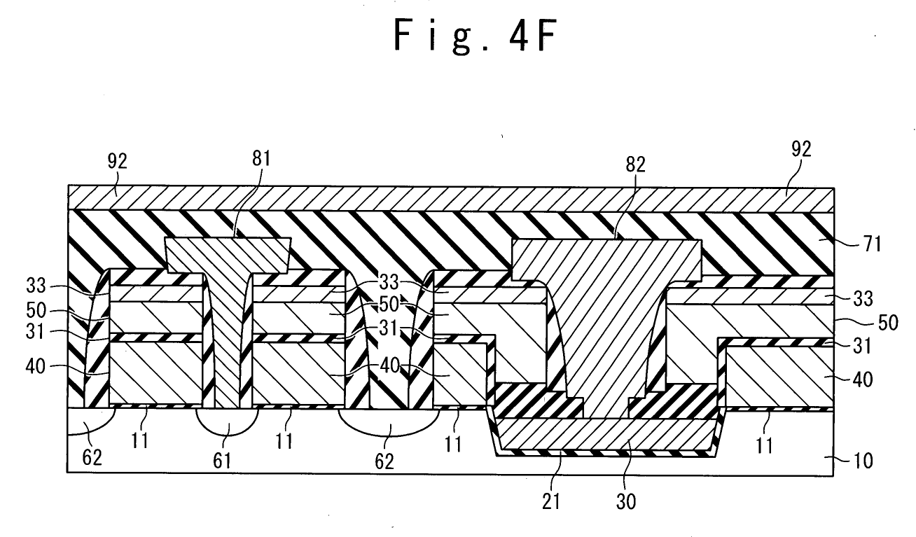

Next, as shown in FIG. 10, the nitride film 14 and the oxide film 13 are removed through an etching. In addition, a part of the oxide film 23 within the trench region 20 is removed through an etching. Here, the etching is performed such that the oxide film 23 is left by a depth of 50 nm or more from the upper surface of the substrate 10.

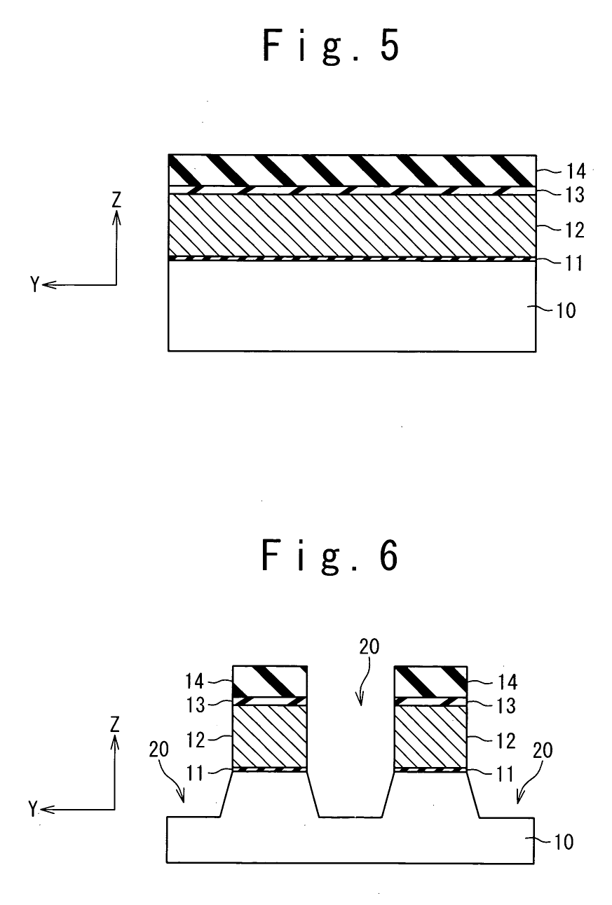

Next, as shown in FIG. 11, a third gate insulating film 31 is formed on an entire surface. The third gate insulating film 31 is, for example, an ONO film with a thickness of about 12 nm. Next, a third polysilicon film 32 with a thickness of about 150 nm is formed on the third gate insulating film 31. The third polysilicon film 32 is doped with N type impurities. Next, a metal film (WSi film) 33 having a thickness of about 100 nm is formed on the third polysilicon film 32, and a nitride film 34 with a thickness of about 100 nm is formed on the metal film 33.

A cross section taken along the line D-D′ in FIG. 3 at this moment is shown in FIG. 12. That is, the first gate insulating film 11 is formed on the substrate 10, and the first polysilicon film 12 is formed on the first gate insulating film 11. The third gate insulating film 31 is formed on the first polysilicon film 12, and the third polysilicon film 32 is formed on the third gate insulating film 31. Further, the metal film 33 is formed on the third polysilicon film 32, and the nitride film 34 is formed on the metal film 33.

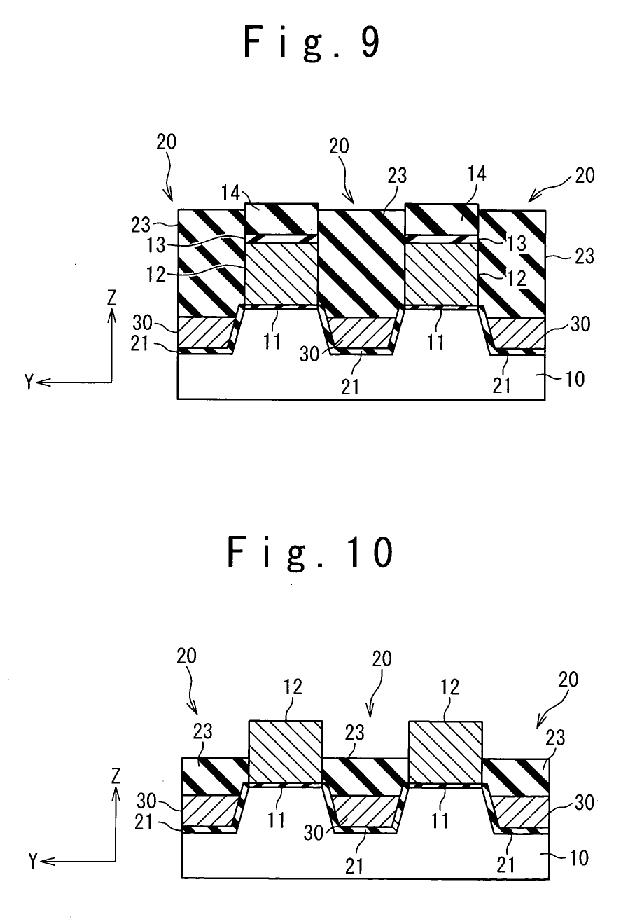

Next, an etching is performed by using a mask having a predetermined pattern along the Y-direction. As a result, the nitride film 34, the metal film 33, the third polysilicon film 32, the third gate insulating film 31, and the first polysilicon film 12 are etched away in this order, and thereby a structure shown in FIG. 13 is obtained. In this way, the above-mentioned floating gate 40 made of the first polysilicon film 12 and the above-mentioned control gate 50 made of the third polysilicon film 32 are obtained.

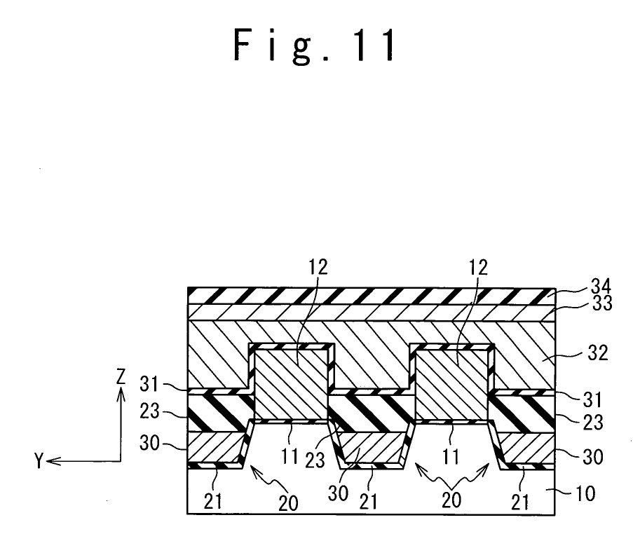

Next, N type impurity ions are implanted into the P type substrate 10 by using the nitride film 34 as a mask. As a result, as shown in FIG. 14, the above-mentioned source region 61 and the drain region 62 are formed in the substrate 10. The source region 61 and the drain region 62 are formed within the substrate 10 on both sides of the floating gate 40 to face each other in the X-direction.

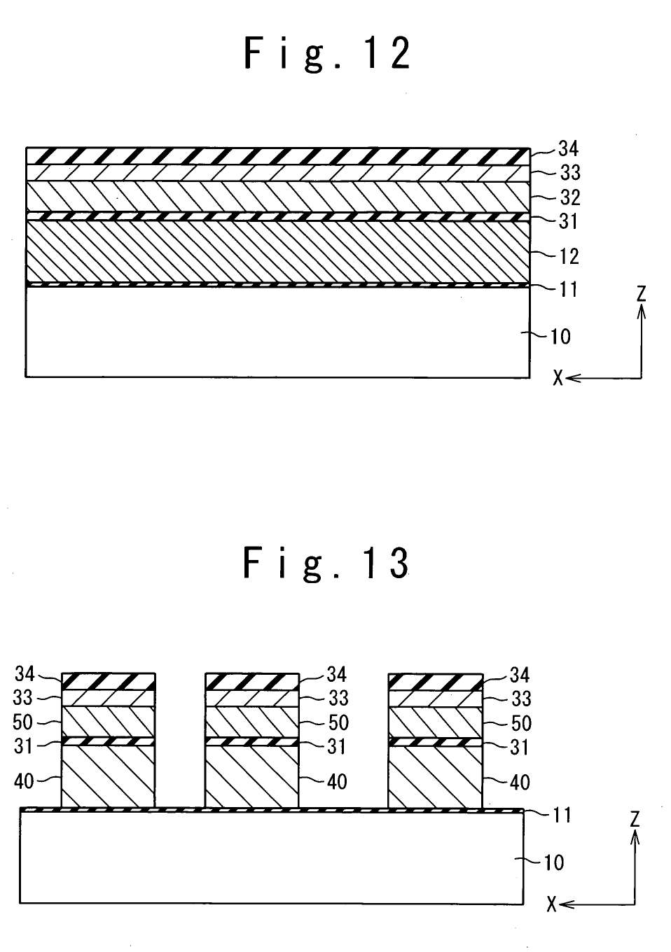

Next, a nitride film is formed on an entire surface, and then an anisotropic etching is performed for the nitride film. As a result, as shown in FIG. 15, gate sidewalls 70 are formed to be adjacent to the control gate 50.

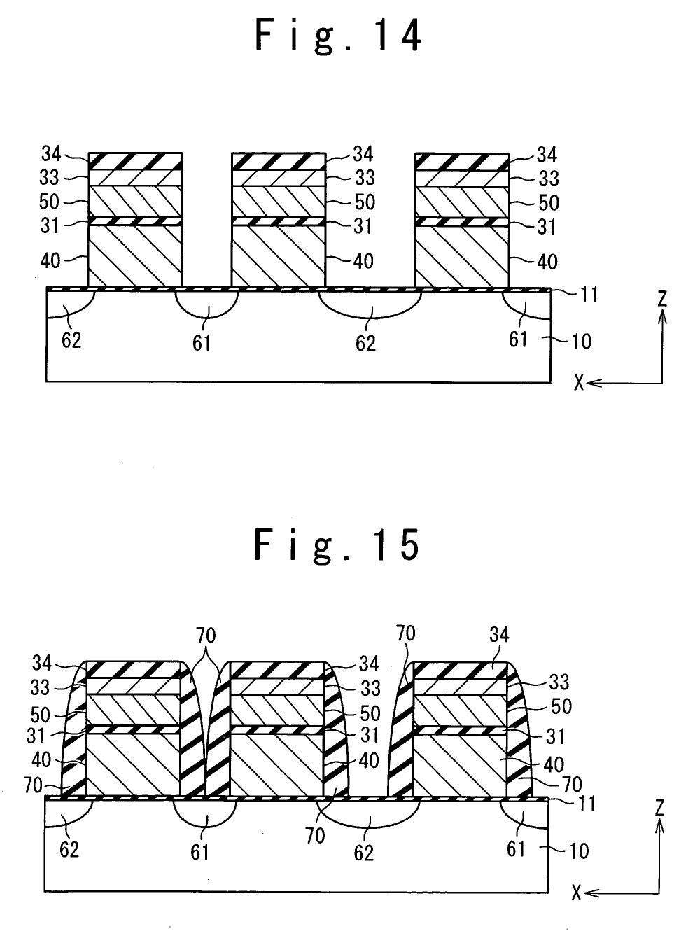

Next, an interlayer insulating film 71 consisting of SiO₂ is formed on an entire surface. Next, as shown in FIG. 16, an opening is formed in the interlayer insulating film 71 such that the source region 61 is exposed. At the same time, in the end section 3 of the memory cell array (see FIG. 3), an opening is formed in the interlayer insulating film 71 such that the buried gate 30 is exposed. These openings are formed to extend in the Y-direction.

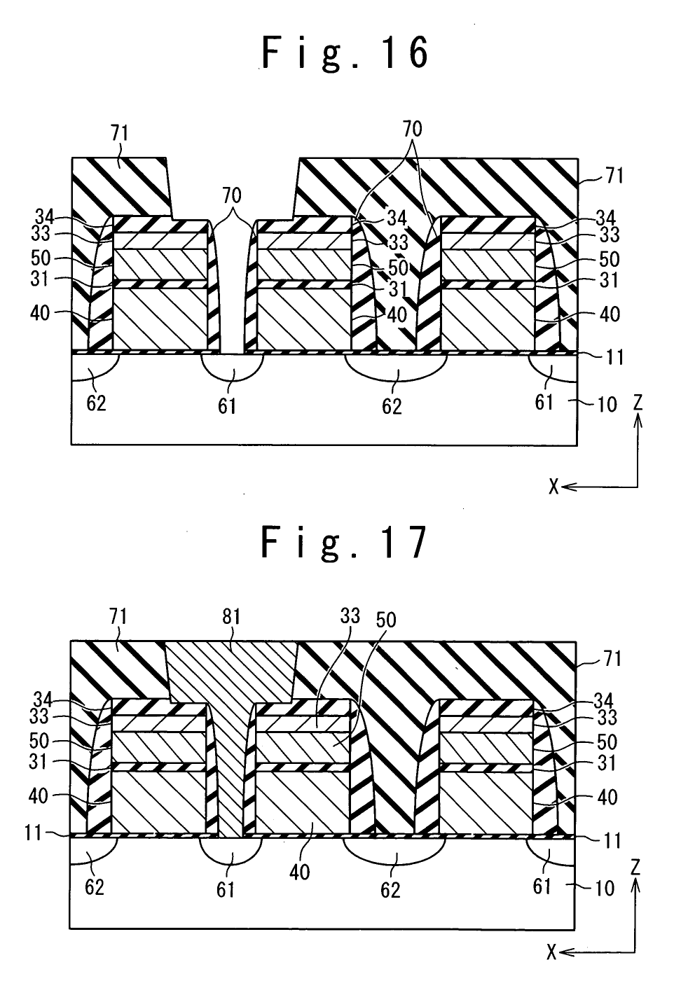

Next, a tungsten film is formed on an entire surface, and then an anisotropic etching is performed for the tungsten film. As a result, the above-mentioned source wiring (first intermediate wiring) 81 penetrating the interlayer insulating film 71 and connected with the source region 61 is formed as shown in FIG. 17. The source wiring 81 is formed in the Y-direction.

At the same time, in the end section 3 of the memory cell array, the above-mentioned buried gate wiring (second intermediate wiring) 82 penetrating the interlayer insulating film 71 and connected with the buried gate 30 is formed as shown in FIG. 18. The buried gate wiring 82 is formed in the Y-direction similarly to the source wirings 81. In this manner, the buried gate wiring 82 for applying the predetermined electric potential to buried gates 30 can be easily formed in the same process as that of forming the source wiring 81.

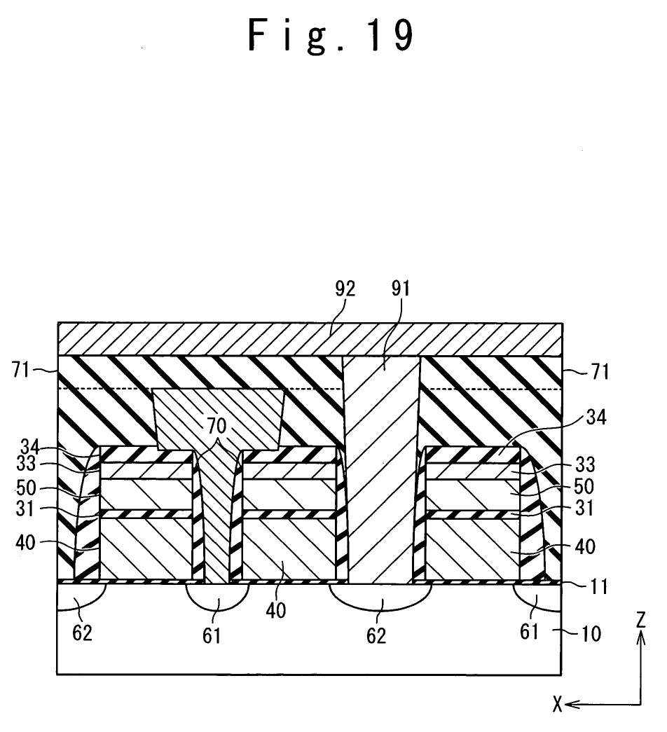

Next, the interlayer insulating film 71 consisting of SiO₂ is additionally formed on the entire surface. Next, an opening is formed in the interlayer insulating film 71 so that the drain region 62 is exposed. Then, a tungsten film is buried into the opening. As a result, as shown in FIG. 19, a contact plug 91 penetrating the interlayer insulating film 71 and connected with the drain region 62 is formed. Next, the above-mentioned drain wiring (upper wiring) 92 consisting of Al is formed on the interlayer insulating film 71 through a predetermined patterning. More specifically, the drain wiring 92 is formed in the X-direction and is provided to be connected to the contact plug 91.

In this manner, the nonvolatile semiconductor memory device 1 according to the present embodiment shown in FIGS. 3 and 4A to 4F can be manufactured.

As stated so far, according to the nonvolatile semiconductor memory device 1 of the present invention, the memory cells are scaled down and the integration density is increased. Moreover, the source resistance is reduced and the operation margin is widened. Furthermore, the malfunctions of the nonvolatile semiconductor memory device 1 are suppressed and hence the yield is improved.

The method of manufacturing the nonvolatile semiconductor memory device includes: (A) a step of forming a first gate insulating film on a substrate; (B) a step of forming a first polysilicon film on said first gate insulating film; (C) a step of forming a trench region in a first direction such that said trench region penetrates said first polysilicon film and said first gate insulating film to reach said substrate; (D) a step of forming a second gate insulating film on a surface of said trench region; (E) a step of forming a second polysilicon film on said second gate insulating film; (F) a step of etching said second polysilicon film to form a buried gate made of said second polysilicon film; (G) a step of forming a third gate insulating film on an entire surface; (H) a step of forming a third polysilicon film on said third gate insulating film; (I) a step of removing said third polysilicon film, said third gate insulating film and said first polysilicon film in a region along a second direction perpendicular to said first direction, to form a floating gate made of said first polysilicon film and a control gate made of said third polysilicon film; (J) a step of forming a source region and a drain region within said substrate on both sides in said first direction of said floating gate, respectively; (K) a step of forming an insulating film on an entire surface; (L) a step of forming a first intermediate wiring in said second direction which penetrates said insulating film and connects to said source region; and (M) a step of forming a second intermediate wiring in said second direction which penetrates said insulating film and connects said buried gate.

It is apparent that the present invention is not limited to the above embodiment, and that may be modified and changed without departing from the scope and spirit of the invention.

What is claimed is:

1. A nonvolatile semiconductor memory device comprising:
a substrate having a trench formed in a first direction;
a floating gate formed on a surface of said substrate outside said trench through a first gate insulating film;
a buried gate formed on a surface of said trench through a second gate insulating film;
a control gate formed to cover said floating gate through a third gate insulating film; and
a source region and a drain region formed in said substrate below said floating gate.

2. The nonvolatile semiconductor memory device according to claim 1,
wherein said buried gate is formed below said first gate insulating film.

3. The nonvolatile semiconductor memory device according to claim 2,
wherein a distance between said buried gate and said first gate insulating film in a depth direction of said trench is equal to or larger than 10 nm.

4. The nonvolatile semiconductor memory device according to claim 1,
wherein a negative electric potential is applied to said buried gate.

5. The nonvolatile semiconductor memory device according to claim 2,
wherein a negative electric potential is applied to said buried gate.

6. The nonvolatile semiconductor memory device according to claim 1,
wherein said buried gate is made of polysilicon.

7. The nonvolatile semiconductor memory device according to claim 2,
wherein said buried gate is made of polysilicon.

8. The nonvolatile semiconductor memory device according to claim 1, further comprising:
a contact plug formed to penetrate an interlayer insulating film to connect with said drain region;
an upper wiring formed on said interlayer insulating film and connected with said contact plug; and
a first intermediate wiring connected with said source region and formed between said upper wiring and said substrate.

9. The nonvolatile semiconductor memory device according to claim 2, further comprising:
a contact plug formed to penetrate an interlayer insulating film to connect with said drain region;
an upper wiring formed on said interlayer insulating film and connected with said contact plug; and
a first intermediate wiring connected with said source region and formed between said upper wiring and said substrate.

10. The nonvolatile semiconductor memory device according to claim 3, further comprising:
a contact plug formed to penetrate an interlayer insulating film to connect with said drain region;
an upper wiring formed on said interlayer insulating film and connected with said contact plug; and
a first intermediate wiring connected with said source region and formed between said upper wiring and said substrate.

11. The nonvolatile semiconductor memory device according to claim 4, further comprising:
a contact plug formed to penetrate an interlayer insulating film to connect with said drain region;
an upper wiring formed on said interlayer insulating film and connected with said contact plug; and
a first intermediate wiring connected with said source region and formed between said upper wiring and said substrate.

12. The nonvolatile semiconductor memory device according to claim 6, further comprising:
a contact plug formed to penetrate an interlayer insulating film to connect with said drain region;
an upper wiring formed on said interlayer insulating film and connected with said contact plug; and
a first intermediate wiring connected with said source region and formed between said upper wiring and said substrate.

13. The nonvolatile semiconductor memory device according to claim 8, further comprising a second intermediate wiring connected to said buried gate,
wherein said second intermediate wiring is formed in a same layer as said first intermediate wiring.

14. The nonvolatile semiconductor memory device according to claim 13,
wherein said first intermediate wiring and said second intermediate wiring are formed in a second direction perpendicular to said first direction.

15. The nonvolatile semiconductor memory device according to claim 9, further comprising a second intermediate wiring connected to said buried gate,
wherein said second intermediate wiring is formed in a same layer as said first intermediate wiring.

16. The nonvolatile semiconductor memory device according to claim 15,
wherein said first intermediate wiring and said second intermediate wiring are formed in a second direction perpendicular to said first direction.

17. The nonvolatile semiconductor memory device according to claim 11, further comprising a second intermediate wiring connected to said buried gate,
wherein said second intermediate wiring is formed in a same layer as said first intermediate wiring.

18. The nonvolatile semiconductor memory device according to claim 17,
wherein said first intermediate wiring and said second intermediate wiring are formed in a second direction perpendicular to said first direction.

19. The nonvolatile semiconductor memory device according to claim 12, further comprising a second intermediate wiring connected to said buried gate,
wherein said second intermediate wiring is formed in a same layer as said first intermediate wiring.

20. The nonvolatile semiconductor memory device according to claim 19,
wherein said first intermediate wiring and said second intermediate wiring are formed in a second direction perpendicular to said first direction.
